(19) United States
(12) Patent Application Publication
(10) Pub. No.: US 2022/0310901 A1
(43) Pub. Date: Sep. 29, 2022

(54) SPIN ORBIT TORQUE DEVICE WITH TOPOLOGICAL INSULATOR AND HEAVY METAL INSERT

(71) Applicant: Intel Corporation, Santa Clara, CA (US)

(72) Inventors: Kaan OGUZ, Portland, OR (US); Tanay GOSAVI, Portland, OR (US); Emily WALKER, Hillsboro, OR (US); Chia-Ching LIN, Portland, OR (US); Ian A. YOUNG, Portland, OR (US)

(21) Appl. No.: 17/211,736

(22) Filed: Mar. 24, 2021

(51) Int. Cl. H01L 43/02; H01L 27/22; H01L 43/06; H01L 43/10

(52) U.S. Cl. CPC H01L 43/02; H01L 27/222; H01L 43/06; H01L 43/10

(57) ABSTRACT

Spin orbit torque (SOT) devices with topological insulator (TI) and heavy metal insert are described. In an example, an integrated circuit structure includes a spin orbit coupling (SOC) interconnect including a TI material. A magnetic layer is above the SOC interconnect. An insert layer includes a heavy metal between and in contact with the TI material and the magnetic layer.

### TECHNICAL FIELD

Embodiments of the disclosure are in the field of integrated circuit structures and, in particular, spin orbit torque (SOT) devices with topological insulator (TI) and heavy metal insert.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased functionality. The drive for ever-more functionality, however, is not without issue. The necessity to optimize the performance of each device becomes increasingly significant.

Non-volatile embedded memory, e.g., on-chip embedded memory with non-volatility can enable energy and computational efficiency. However, leading embedded memory options such as spin torque transfer magnetoresistive random access memory (STT-MRAM) can suffer from high voltage and high current-density problems during the programming (writing) of the cell. Furthermore, the density limitations of STT-MRAM may be due to large write switching current and select transistor requirements. Specifically, traditional STT-MRAM has a cell size limitation due to the drive transistor requirement to provide sufficient spin current. Furthermore, such memory is associated with large write current (>100 μA) and voltage (>0.7 V) requirements of conventional magnetic tunnel junction (MTJ) based devices. Endurance is also a challenge for STT-MRAM due to tunnel barrier failure.

As such, significant improvements are still needed in the area of non-volatile memory arrays based on MTJs and/or logic devices based on magnetic layers.

### BRIEF DESCRIPTION OF THE DRAWINGS

FIG. 1A illustrates a state of the art material stack for a spin orbit torque (SOT) based Magnetic Tunnel Junction (MTJ) memory device.

FIG. 1B illustrates a material stack for a spin orbit torque (SOT) based Magnetic Tunnel Junction (MTJ) memory device, in accordance with an embodiment of the present disclosure.

FIG. 2A illustrates an antiferromagnetic (AFM)-based spin orbit torque (SOT) memory device.

FIG. 2B is a top view of the device of FIG. 2A.

FIG. 2C is a cross-section of the spin orbit torque (SOT) layer that shows direction of spin currents and charge currents as decided by SOT in metals.

FIG. 2D illustrates an antiferromagnetic (AFM)-based spin orbit torque (SOT) memory device, in accordance with an embodiment of the present disclosure.

FIG. 3 is a plot of spin hall angle (SHA) as a function of spin orbit (SO) material, in accordance with an embodiment of the present disclosure.

FIG. 4 illustrates cross-sectional views of a magnetic layer or antiferromagnetic layer in contact with an insert stack including a plurality of alternating topological insulator layers and heavy metal layers, in accordance with an embodiment of the present disclosure.

FIGS. 5A and 5B illustrate a wafer composed of semiconductor material and that includes one or more dies having integrated circuit (IC) structures formed on a surface of the wafer, in accordance with an embodiment of the present disclosure.

FIG. 6 is a cross-sectional side view of an integrated circuit (IC) device assembly that may include one or more spin orbit torque devices with topological insulator and heavy metal insert, in accordance with an embodiment of the present disclosure.

FIG. 7 illustrates a computing device in accordance with one implementation of the disclosure.

### DESCRIPTION OF THE EMBODIMENTS

Spin orbit torque (SOT) devices with topological insulator (TI) and heavy metal insert are described. In the following description, numerous specific details are set forth, such as specific material and tooling regimes, in order to provide a thorough understanding of embodiments of the present disclosure. It will be apparent to one skilled in the art that embodiments of the present disclosure may be practiced without these specific details. In other instances, well-known features, such as single or dual damascene processing, are not described in detail in order to not unnecessarily obscure embodiments of the present disclosure. Furthermore, it is to be understood that the various embodiments shown in the Figures are illustrative representations and are not necessarily drawn to scale. In some cases, various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

Certain terminology may also be used in the following description for the purpose of reference only, and thus are not intended to be limiting. For example, terms such as “upper”, “lower”, “above”, “below,” “bottom,” and “top” refer to directions in the drawings to which reference is made. Terms such as “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

Embodiments described herein may be directed to front-end-of-line (FEOL) semiconductor processing and structures. FEOL is the first portion of integrated circuit (IC) fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may be directed to back-end-of-line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than 10 metal layers may be added in the BEOL.

Embodiments described below may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

One or more embodiments of the present disclosure is directed to enhanced spin orbit torque efficiency in topological insulators for spin orbit torque magnetoresistive random access memory (SOT-MRAM) and magneto-electric spin orbit (MESO) logic.

To provide context, there is a need for a high-spin hall angle (SHA) (θ_{SH}) material to reduce switching current in SOT-MRAM and enhance output of a MESO logic device. Presently, heavy metals and topological insulators are being used as SOT materials but can be associated with an insufficient SHA.

In accordance with an embodiment of the present disclosure, a heavy metal insert layer is included between a topological insulator and a magnetic layer. The insert can enhance the SHA by 2×. Advantages for implementing embodiments described herein can include providing a high SHA for the application of SOT materials in both SOT-MRAM and MESO logic devices to reduce power consumption and enhance output signal, respectively. In conventional SOT-MRAM and MESO stacks, topological insulators or heavy metals are in direct contact with the magnetic layer. By contrast, one or more embodiments described herein include a heavy metal insert between the magnetic layer and SOT material. The heavy metal insert can be implemented to reduce reaction at the magnetic layer interface for the topological insulator. It can also enhance the spin polarization of the topological surface states.

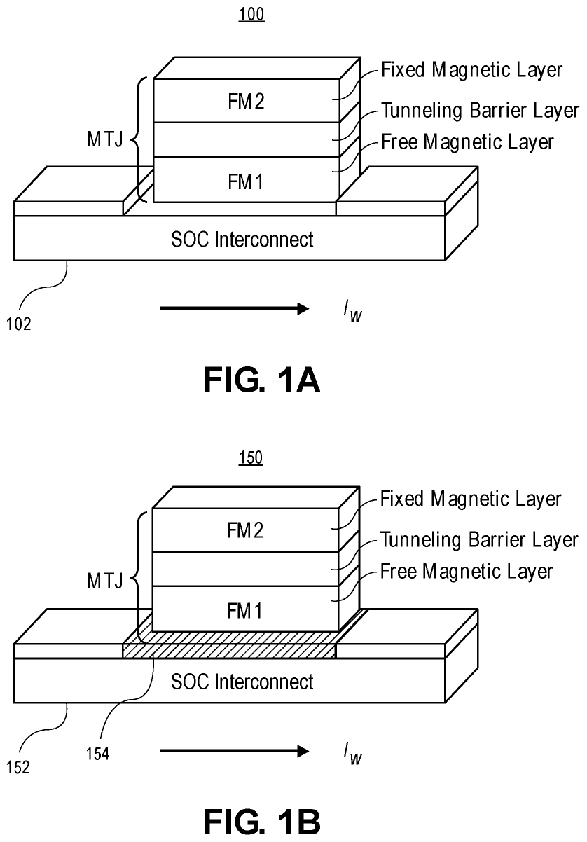

In order to provide context, FIG. 1 illustrates a state of the art material stack 100 for a SOT (Spin Orbit Torque) based MTJ (Magnetic Tunnel Junction) memory device, according to one embodiment. The MTJ material stack 100 stores data as a resistance state value. The MTJ device stack includes two independent ferromagnetic (FM) layers referred to as a free magnetic layer (FM1) and a reference fixed magnetic layer (FM2) that are separated by an insulating tunneling barrier layer. The material for the tunneling barrier layer is sufficiently thin such that electrons can tunnel there through. The magnetic field of the free magnetic layer FM1 is free to rotate based on a direction of a current, i.e., the spin of the electrons, flowing through the MTJ device stack. In contrast, the fixed magnetic layer has a fixed magnetization, and is therefore referred to as a fixed or reference layer. The free magnetic layer FM1 of the material stack is in direct contact with an interconnect 102, e.g., a write electrode, including a spin orbit coupling (SOC) material.

The MTJ functions essentially as a resistor, where the resistance of an electrical path through the MTJ may exist in two resistive states, either “high” or “low,” depending on the direction or orientation of magnetization in the free magnetic layer FM1 and in the fixed magnetic FM2. In the case that the directions of magnetization in the free magnetic layer FM1 and the fixed magnetic FM2 closest to it are substantially not aligned or not parallel with one another (typically two are perpendicular to each other), a high resistive state exists. In the case that the directions of magnetization in the coupled free magnetic layer and the fixed magnetic layer closest to it are substantially aligned or parallel with one another, a low resistive state exists. It is to be understood that the terms “low” and “high” with regard to the resistive state of the MTJ are relative to one another. In other words, the high resistive state is merely a detectibly higher resistance than the low resistive state, and vice versa. Thus, with a detectible difference in resistance, the low and high resistive states can represent different bits of information (i.e., a “0” or a “1”).

In some embodiments, the MTJ may further include a synthetic antiferromagnetic (SAF) stack (not shown) over the MTJ to cancel dipole fields around the free magnetic layer FM1. A top electrode (not shown) completes the material stack. A wide combination of materials can be used for material stacking of the MTJ device and the SAF stack. For example, in the embodiment shown, the free magnetic layer FM1 and the fixed magnetic layer FM2 may both include CoₓFe_{y}B_{z} (Cobalt, Iron, Boron), where ‘x,’ ‘y,’ and ‘z’ are integers. The barrier material typically includes an oxide layer such as magnesium oxide (MgO).

An SOT material stack when used as a perpendicular spin-orbit torque (pSOT) device is one of the promising e-SRAM solutions for future technology nodes. However, providing a stable p-MTJ stack on SOC material interconnect 102 presents a challenges, such as ensuring sufficiently fast switching and a stable SAF stack.

More specifically, one or more embodiments target the use or application of an antiferromagnetic (AFM) based spin orbit torque (SOT) memory device, such as an e-MRAM or e-SRAM, having an interconnect including a spin orbit coupling material. A free layer magnet including an AFM (rather than a ferromagnetic) is on the interconnect, a barrier material is over the free layer magnet and a reference fixed magnet is over the barrier material. In another aspect, a memory device includes a spin orbit coupling (SOC) interconnect and an AFM free magnetic layer on the interconnect. A ferromagnetic magnetic tunnel junction (MTJ) device is on the AFM free magnetic layer, wherein the ferromagnetic MTJ includes a free magnet layer, a fixed magnet layer, and a barrier material between the free magnet layer and the fixed magnet layer. According to the disclosed embodiments, the AFM based SOT memory device has fast switching, high thermal stability, flexible geometry, and little to no stray field.

By contrast to FIG. 1A, an integrated circuit (IC) structure includes an insert layer. As an example, FIG. 1B illustrates a material stack for a SOT (Spin Orbit Torque) based MTJ (Magnetic Tunnel Junction) memory device, in accordance with an embodiment of the present disclosure.

With reference to FIG. 1B, in an embodiment, an integrated circuit structure 150 includes a spin orbit coupling (SOC) interconnect 152 including a topological insulator material. A magnetic layer FM1 (e.g., CoFeB or NiFe) is above the SOC interconnect 152. An insert layer 154 includes a heavy metal between and in contact with the topological insulator material and the magnetic layer FM1.

In one embodiment, not depicted, a magneto-electric spin orbit (MESO) logic device is fabricated using insert layer 154 between and in contact with a topological insulator material and a magnetic layer. In another embodiment, as depicted, structure 150 is for MRAM. In the latter case, the magnetic layer is a free magnetic layer, and the integrated circuit (IC) structure further includes a barrier material over the free magnetic layer and a fixed magnetic layer over the barrier material.

In one embodiment, the topological insulator material of the SOC interconnect 152 includes a material selected from the group consisting of Bi₂Se₃, Bi₂Te₃, Sb₂Se₃, Sb₂Te₃ and BiₓSb₁₋ₓTe₃. In one embodiment, the heavy metal of the insert layer 154 includes tantalum, tungsten, iridium, platinum, or an alloy thereof. In one embodiment, wherein the topological insulator material of the SOC interconnect 152 has a thickness in the range of 5-15 nanometers, and the insert layer 154 has a thickness in the range of 0.5-5 nanometers.

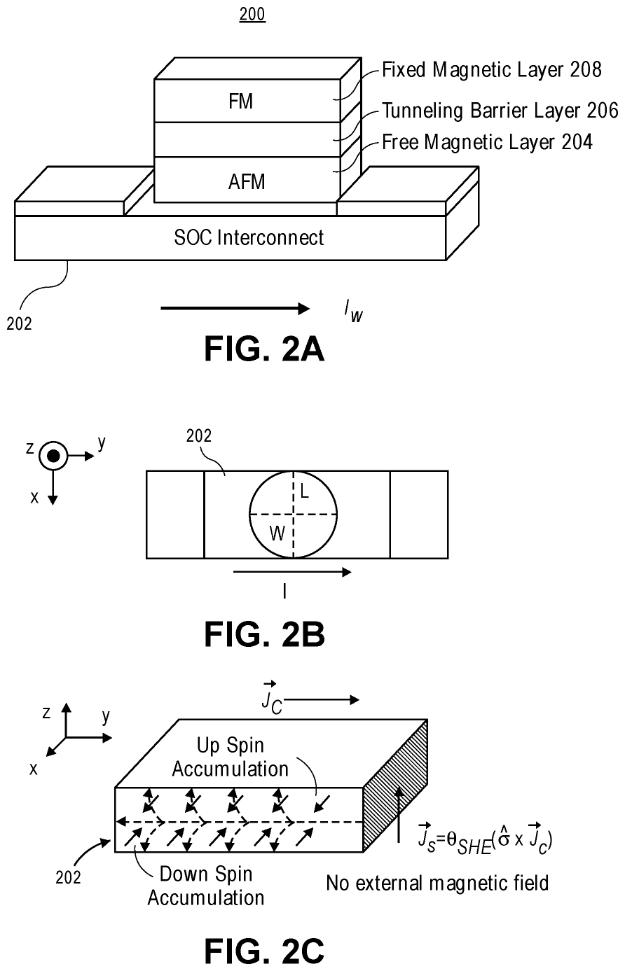

In another aspect, one or more embodiments of the present disclosure are directed to an antiferromagnetic (AFM) based spin orbit torque (SOT) memory device. General applications of such an array include, but are not limited to, magnetic tunnel junction (MTJ) architectures, MRAM, non-volatile memory, spin torque memory, and embedded memory using magnetic memory devices. In accordance with various embodiments of the present disclosure, an improved SOT-MRAM memory, and more particularly, an improved perpendicular SOT embedded Static RAM (e-SRAM) and/or e-MRAM is described below. In one embodiment, an antiferromagnetic (AFM) material is used to replace a ferromagnet as the free magnetic layer in the SOT stack of the SOT memory devices to increase switching speed and provide higher thermal stability, as shown in FIGS. 2A-2C.

FIG. 2A illustrates an antiferromagnetic (AFM)-based spin orbit torque (SOT) memory device. In one embodiment, the AFM-based SOT memory device may include a perpendicular spin orbit torque (pSOT) memory device 200. The pSOT memory device 200 includes an interconnect including a spin orbit coupling (SOC) material to provide a SOC interconnect 202. A free magnetic layer 204 is on the SOC interconnect 202, a tunneling barrier layer 206 is over the free magnetic layer 204 and a fixed magnetic layer 208 is over the tunneling barrier layer 206, wherein according to the disclosed embodiments, the free magnetic layer 204 includes an AFM, rather than a ferromagnet.

In certain aspects and in at least some embodiments of the present disclosure, certain terms hold certain definable meanings. The free magnetic layer 204, the tunneling barrier layer 206, and the fixed magnetic layer 208 include an AFM-based device stack. The free magnetic layer 204 of the material stack is on and in contact with the SOC interconnect 202, e.g., a write electrode. The magnetic field of the free magnetic layer 204 is free to rotate based on a direction of a current, i.e., the spin of the electrons, flowing through the AFM device stack. For example, the free magnetic layer 204 is an AFM layer storing a computational variable. In contrast, the fixed magnetic layer 208 has a fixed magnetization, and is therefore referred to as a fixed or reference layer that is magnetically harder than the free magnetic layer.

In one embodiment, the free magnetic layer 204 includes an AFM material including one of: Ir, Pt, Mn, Pd, Ge, Ga or Fe. In some embodiments, the AFM material is a quasi-two-dimensional triangular AFM including Ni(1−x)MxGa2S4, where ‘M’ includes one of: Mn, Fe, Co or Zn. The AFM material may range in thickness from approximately 1 to 20 nm.

In one embodiment, the fixed magnetic layer 208 includes a ferromagnet (FM) including any combination of: CFGG (i.e., Cobalt (Co), Iron (Fe), Germanium (Ge), and Gallium (Ga)). In some embodiments, the fixed magnetic layer 208 includes one or more of Co, Fe, Ni alloys and multilayer hetero-structures, various oxide ferromagnets, garnets, or Heusler alloys. For example, CoFeB, FeB, CoFe, LaSrMnO3(LSMO), Co/Pt, CoFeGd, and ferromagnetic (FM) semi-metal such as Weyl, and Heusler alloy such as Cu2MnAl, Cu2MnIn, Cu2MnSn can be used for the fixed magnetic layer 208. Heusler alloys are FM metal alloys based on a Heusler phase. Heusler phases are intermetallic with certain composition and face-centered cubic crystal structure. The FM property of the Heusler alloys are a result of a double-exchange mechanism between neighboring magnetic ions. In some embodiments, the Heusler alloy includes one of: Cu2MnAl, Cu2MnIn, Cu2MnSn, Ni2MnAl, Ni2MnIn, Ni2MnSn, Ni2MnSb, Ni2MnGa Co2MnAl, Co2MnSi, Co2MnGa, Co2MnGe, Pd2MnAl, Pd2MnIn, Pd2MnSn, Pd2MnSb, Co2FeSi, Co2FeAl, Fe2VAl, Mn2VGa, Co2FeGe, MnGa, or MnGaRu. The fixed magnetic layer 208 may range in thickness from approximately 1 to 20 nm.

The tunneling barrier layer 206, such as a tunneling dielectric or oxide layer, is one located between free magnetic layer 204 and fixed magnetic layer 208. In one embodiment, tunneling barrier layer 206 may include one of Mg, Al, or Ti. In one embodiment, tunneling barrier layer 206 may range in thickness from approximately 0.5 to 10 nm.

FIG. 2B is a top view of the device of FIG. 2A. In FIG. 2B, the magnet is oriented along the width of the interconnect 202 or write electrode for appropriate spin injection. The magnetic cell is written by applying a charge current (I) via the spin orbit coupling (SOC) interconnect 202. The direction of the magnetic writing is decided by the direction of the applied charge current. Positive currents (along+y) produce a spin injection current with transport direction (along+z) and spins pointing to (+x) direction. The SOC material of interconnect 202 can impact both perpendicular and in plane magnetic free layers, and this disclosure may apply to both. Because what is known as the Spin Hall Effect may be responsible for the current-induced magnetization switch in the MTJ device, an SOT-MRAM may also be referred to as a Giant Spin Hall Effect (GSHE) MRAM.

In some embodiments, the SOC material of interconnect 202 (or the write electrode) includes 3D materials such as one or more of β-Tantalum (β-Ta), Ta, β-Tungsten (β-W), W, Pt, Copper (Cu) doped with elements such as Iridium, Bismuth and any of the elements of 3d, 4d, 5d and 4f, 5f periodic groups in the Periodic Table which may exhibit high spin orbit coupling. In some embodiments, the SOC interconnect 202 includes one or more of: Pt, Ta, W, WOx, CuBi, BiOx, Bi2Se3, Bi2Sb3, SrIrO3, or a stack of LaAlO3 (LAO) and SrTiO3 (STO). The thickness is ranges from approximately 1 to 20 nm.

FIG. 2C is a cross-section of the SOC interconnect 202 that shows direction of spin currents and charge currents as decided by SOC in metals. The injected spin current in-turn produces spin torque to align the magnet in the +x or −x direction. The transverse spin current for a charge current in the write electrode is provided in equation (1):

Iₛ=Pₛₕₑ(w,t,λ_{sf}, θ_{SHE})(σxI_{c}) (1)

where P_{SHE} is the spin hall injection efficiency, which is the ratio of magnitude of transverse spin current to lateral charge current, w is the width of the magnet, t is the thickness of the GSHE metal electrode, λ_{sf} is the spin flip length in the GSHE metal, θ_{GSHE} is the spin hall angle (SHA) for the GSHE-metal to the AFM free magnetic layer interface. The injected spin angular momentum responsible for spin torque can be determined by first solving equation 1.

By contrast to FIG. 2A, an integrated circuit structure includes an insert layer. As an example, FIG. 2D illustrates an antiferromagnetic (AFM)-based spin orbit torque (SOT) memory device, in accordance with an embodiment of the present disclosure.

With reference to FIG. 2D, in an embodiment, an integrated circuit structure 250 includes a spin orbit coupling (SOC) interconnect 252 including a topological insulator material. An antiferromagnetic layer AFM is above the SOC interconnect 252. An insert layer 254 includes a heavy metal between and in contact with the topological insulator material and the antiferromagnetic layer AFM.

In one embodiment, not depicted, a magneto-electric spin orbit (MESO) logic device is fabricated using insert layer 254 between and in contact with a topological insulator material and a magnetic layer. In another embodiment, as depicted, structure 250 is for MRAM. In the latter case, the antiferromagnetic layer AFM is a free antiferromagnetic layer AFM, and the integrated circuit structure further includes a barrier material 256 over the free antiferromagnetic layer AFM and a fixed magnetic layer 258 over the barrier material 256.

In one embodiment, the topological insulator material of the SOC interconnect 252 includes a material selected from the group consisting of Bi₂Se₃, Bi₂Te₃, Sb₂Se₃, Sb₂Te₃ and BiₓSb₁₋ₓTe₃. In one embodiment, the heavy metal of the insert layer 254 includes tantalum, tungsten, iridium, platinum, or an alloy thereof. In one embodiment, wherein the topological insulator material of the SOC interconnect 252 has a thickness in the range of 5-15 nanometers, and the insert layer 254 has a thickness in the range of 0.5-5 nanometers.

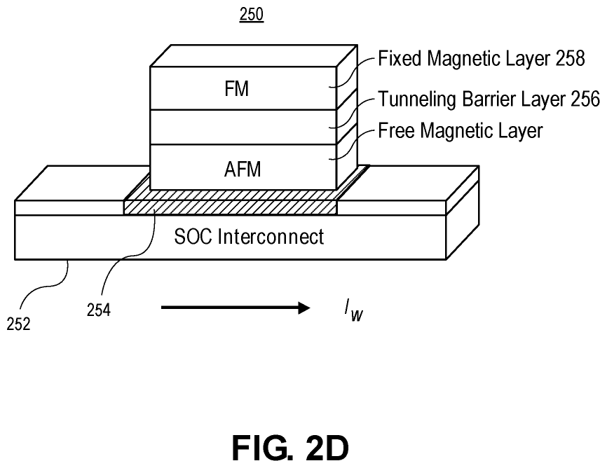

FIG. 3 is a plot 300 of spin hall angle (SHA) as a function of spin orbit (SO) material, in accordance with an embodiment of the present disclosure. From left to right, the SO material is beta-tungsten, Bi2Te3, Bi2Te3 with tungsten insert, Sb2Te3, and Sb2Te3 with tungsten insert.

Referring to plot 300, the SHA measured by ST-FMR for different SOT materials reveals that BiTe and SbTe with W insert show >1.5-2× enhancement due to reduced dead layer and diffusion between a magnetic layer and a topological insulator (TI).

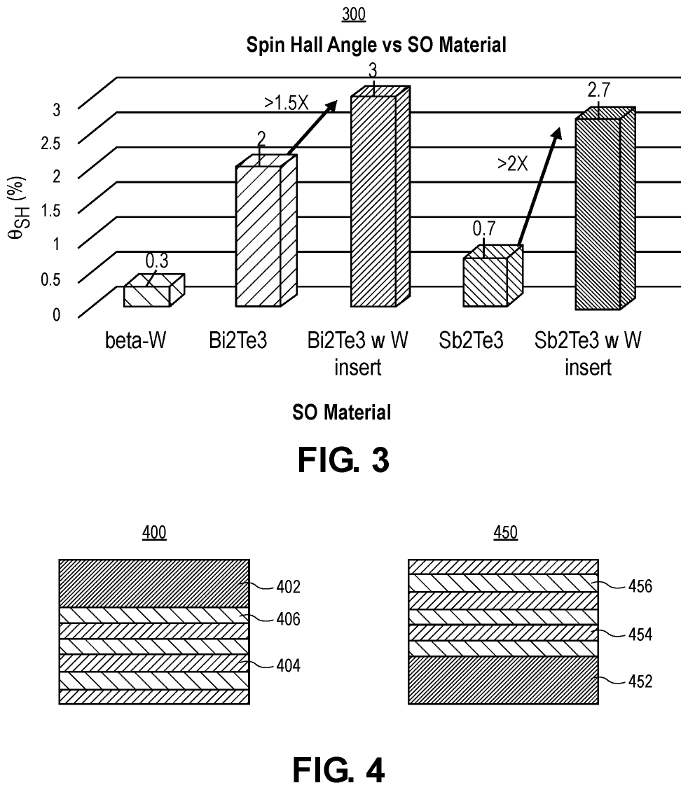

In another aspect, an insert stack can be used in place of a single layer. As an example, FIG. 4 illustrates cross-sectional views of a magnetic layer or antiferromagnetic layer AFM in contact with an insert stack including a plurality of alternating topological insulator (TI) layers and heavy metal layers, in accordance with an embodiment of the present disclosure. The left-hand structure 400 includes a magnetic or antiferromagnetic layer AFM 402 in contact with an insert stack including a plurality of alternating TI layers 404 and heavy metal layers 406. The right-hand structure 450 includes a magnetic or antiferromagnetic layer AFM 452 in contact with an insert stack including a plurality of alternating topological insulator layers 454 and heavy metal layers 456.

With reference to the left-hand structure of FIG. 4, in an embodiment, an integrated circuit structure includes a spin orbit coupling (SOC) interconnect (not shown). A magnetic or antiferromagnetic layer AFM 402 is above the SOC interconnect. An insert stack is between the SOC interconnect and the magnetic or antiferromagnetic layer 402. The insert stack includes a plurality of alternating topological insulator material layers 404 and heavy metal layers 406 with one of the heavy metal layers 406 in contact with the magnetic or antiferromagnetic layer AFM 402.

In one embodiment, the magnetic or antiferromagnetic layer AFM 402 is a free magnetic or antiferromagnetic (AFM) layer, and the integrated circuit (IC) structure further includes a tunneling barrier layer over the free magnetic layer or AFM layer and a fixed magnetic layer over the tunneling barrier layer. In one embodiment, the topological insulator (TI) material layers 404 include a material selected from the group consisting of Bi₂Se₃, Bi₂Te₃, Sb₂Se₃, Sb₂Te₃ and BiₓSb₁₋ₓTe₃. In one embodiment, the heavy metal layers 406 include tantalum, tungsten, iridium, platinum, or an alloy thereof. In one embodiment, each of the topological insulator layers has a thickness in the range of 5-15 nanometers, and each of the heavy metal layers has a thickness in the range of 0.5-5 nanometers.

In an embodiment, a spin orbit coupling (SOC) interconnect is formed in an opening in a dielectric layer above a substrate. The substrate may include a suitable semiconductor material such as but not limited to, single crystal silicon, polycrystalline silicon, and silicon on insulator (SOI). In another embodiment, the substrate may include other semiconductor materials such as germanium, silicon germanium or a suitable group III-N or a group III-V compound.

In an embodiment, the SOC interconnect is formed in the dielectric layer by a damascene or a dual damascene process. In an embodiment, both the SOC interconnect and the write electrode may include a Giant Spin Hall Effect (GSHE) metal made of β-Tantalum (β-Ta), β-Tungsten (β-W), W, Pt, Copper (Cu) doped with elements such as Iridium, Bismuth and any of the elements of 3d, 4d, 5d and 4f, 5f periodic groups in the periodic table. In an embodiment, the SOC interconnect is electrically connected to a circuit element such as an access transistor (not shown). Logic devices such as access transistors may be integrated with memory devices to form embedded memory.

In one embodiment, the material layers of the above structures are blanket deposited. The layers may be formed by sputter-deposition techniques with deposition rates in the Ångstrom-per-second range. The techniques include physical vapor deposition (PVD) such as planar magnetron sputtering, ion-beam deposition, an evaporation process, an atomic layer deposition (ALD) process, MOCVD process or by a chemical vapor deposition (CVD) process. In an embodiment, the chemical vapor deposition process is enhanced by plasma techniques such as RF glow discharge (plasma enhanced CVD) to increase the density and uniformity of the film. In an embodiment, an uppermost layer of a material layer stack may include the top electrode layer that ultimately acts as a hardmask. The deposition process can be configured to control the magnetic properties of the magnetic layers. For example, the direction of the magnetic anisotropy of the ferromagnetic (FM) materials can be set during the deposition of the layer by applying a magnetic field across the wafer. The resulting uniaxial anisotropy is observed as magnetic easy and hard directions in the magnetization of the layer. Since the anisotropy axis affects the switching behavior of the material, the deposition system must be capable of projecting a uniform magnetic field across the wafer, typically in the 20-100 Oe range, during deposition. The deposition process can control other magnetic properties, such as coercivity and magnetorestriction, by the choice of magnetic alloy and deposition conditions. Because the switching field of a patterned bit depends directly on the thickness of the free layer magnet, the thickness uniformity and repeatability must meet strict requirements.

It is to be appreciated that the layers and materials described in association with embodiments herein are typically formed on or above an underlying semiconductor substrate, e.g., as front-end-of-line (FEOL) layer(s). In other embodiments, the layers and materials described in association with embodiments herein are formed on or above underlying device layer(s) of an integrated circuit, e.g., as back-end-of-line (BEOL) layer(s). In an embodiment, an underlying semiconductor substrate represents a general workpiece object used to manufacture integrated circuits. The semiconductor substrate often includes a wafer or other piece of silicon or another semiconductor material. Suitable semiconductor substrates include, but are not limited to, single crystal silicon, polycrystalline silicon, and silicon on insulator (SOI), as well as similar substrates formed of other semiconductor materials. The semiconductor substrate, depending on the stage of manufacture, often includes transistors, integrated circuitry, and the like. The substrate may also include semiconductor materials, metals, dielectrics, dopants, and other materials commonly found in semiconductor substrates. Furthermore, although not depicted, structures described herein may be fabricated on underlying lower level BEOL interconnect layers. For example, in one embodiment, a spin orbit torque (SOT) device with topological insulator (TI) and heavy metal insert is formed on a material composed of a dielectric material such as, but not limited to, silicon dioxide, silicon oxy-nitride, silicon nitride, or carbon-doped silicon nitride. In a particular embodiment, an embedded non-volatile memory structure is formed on a low-k dielectric layer of an underlying BEOL layer.

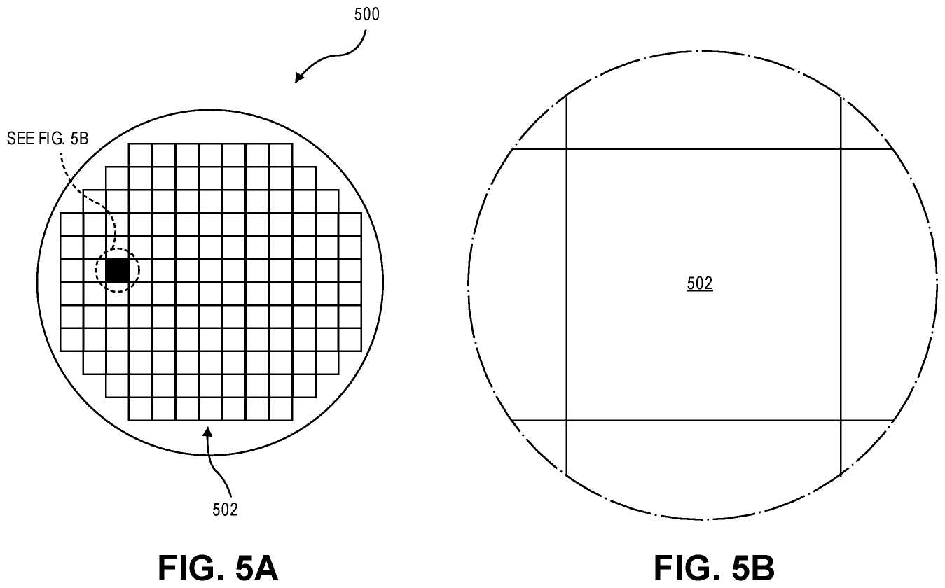

Referring to FIGS. 5A and 5B, a wafer 500 may be composed of semiconductor material and may include one or more dies 502 having integrated circuit (IC) structures formed on a surface of the wafer 500. Each of the dies 502 may be a repeating unit of a semiconductor product that includes any suitable IC (e.g., ICs including one or more spin orbit torque (SOT) devices with topological insulator and heavy metal insert, such as described above). After the fabrication of the semiconductor product is complete, the wafer 500 may undergo a singulation process in which each of the dies 502 is separated from one another to provide discrete “chips” of the semiconductor product. In particular, structures that include a SOT device with topological insulator (TI) and heavy metal insert as disclosed herein may take the form of the wafer 500 (e.g., not singulated) or the form of the die 502 (e.g., singulated). The die 502 may include one or more SOT devices with TI and heavy metal insert and/or supporting circuitry to route electrical signals, as well as any other IC components. In some embodiments, the wafer 500 or the die 502 may include an additional memory device (e.g., a static random access memory (SRAM) device), a logic device (e.g., an AND, OR, NAND, or NOR gate), or any other suitable circuit element. Multiple ones of these devices may be combined on a single die 502. For example, a memory array formed by multiple memory devices may be formed on a same die 502 as a processing device or other logic that is configured to store information in the memory devices or execute instructions stored in the memory array.

Embodiments disclosed herein may be used to manufacture a wide variety of different types of integrated circuits and/or microelectronic devices. Examples of such integrated circuits include, but are not limited to, processors, chipset components, graphics processors, digital signal processors, micro-controllers, and the like. In other embodiments, semiconductor memory or logic may be manufactured. Moreover, the integrated circuits or other microelectronic devices may be used in a wide variety of electronic devices known in the art. For example, in computer systems (e.g., desktop, laptop, server), cellular phones, personal electronics, etc. The integrated circuits may be coupled with a bus and other components in the systems. For example, a processor may be coupled by one or more buses to a memory, a chipset, etc. Each of the processor, the memory, and the chipset, may potentially be manufactured using the approaches disclosed herein.

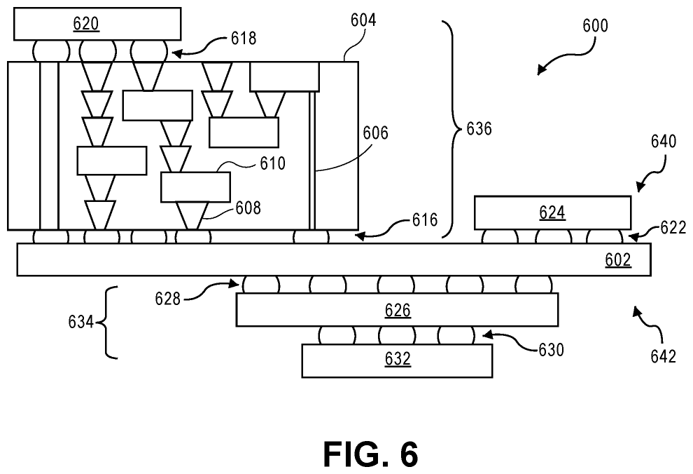

FIG. 6 is a cross-sectional side view of an integrated circuit (IC) device assembly that may include one or more spin orbit torque (SOT) devices with topological insulator (TI) and heavy metal insert, in accordance with one or more of the embodiments disclosed herein.

Referring to FIG. 6, an IC device assembly 600 includes components having one or more IC structures described herein. The IC device assembly 600 includes a number of components disposed on a circuit board 602 (which may be, e.g., a motherboard). The IC device assembly 600 includes components disposed on a first face 640 of the circuit board 602 and an opposing second face 642 of the circuit board 602. Generally, components may be disposed on one or both faces 640 and 642. In particular, any suitable ones of the components of the IC device assembly 600 may include a number of SOT devices with TI and heavy metal insert, such as disclosed herein.

In some embodiments, the circuit board 602 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 602. In other embodiments, the circuit board 602 may be a non-PCB substrate.

The IC device assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), male and female portions of a socket, an adhesive, an underfill material, and/or any other suitable electrical and/or mechanical coupling structure.

The package-on-interposer structure 636 may include an IC package 620 coupled to an interposer 604 by coupling components 618. The coupling components 618 may take any suitable form for the application, such as the forms discussed above with reference to the coupling components 616. Although a single IC package 620 is shown in FIG. 6, multiple IC packages may be coupled to the interposer 604. It is to be appreciated that additional interposers may be coupled to the interposer 604. The interposer 604 may provide an intervening substrate used to bridge the circuit board 602 and the IC package 620. The IC package 620 may be or include, for example, a die (the die 502 of FIG. 5B), or any other suitable component. Generally, the interposer 604 may spread a connection to a wider pitch or reroute a connection to a different connection. For example, the interposer 604 may couple the IC package 620 (e.g., a die) to a ball grid array (BGA) of the coupling components 616 for coupling to the circuit board 602. In the embodiment illustrated in FIG. 6, the IC package 620 and the circuit board 602 are attached to opposing sides of the interposer 604. In other embodiments, the IC package 620 and the circuit board 602 may be attached to a same side of the interposer 604. In some embodiments, three or more components may be interconnected by way of the interposer 604.

The interposer 604 may be formed of an epoxy resin, a fiberglass-reinforced epoxy resin, a ceramic material, or a polymer material such as polyimide. In some implementations, the interposer 604 may be formed of alternate rigid or flexible materials that may include the same materials described above for use in a semiconductor substrate, such as silicon, germanium, and other group III-V and group IV materials. The interposer 604 may include metal interconnects 610 and vias 608, including but not limited to through-silicon vias (TSVs) 606. The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio-frequency (RF) devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art.

The IC device assembly 600 may include an IC package 624 coupled to the first face 640 of the circuit board 602 by coupling components 622. The coupling components 622 may take the form of any of the embodiments discussed above with reference to the coupling components 616, and the IC package 624 may take the form of any of the embodiments discussed above with reference to the IC package 620.

The IC device assembly 600 illustrated in FIG. 6 includes a package-on-package structure 634 coupled to the second face 642 of the circuit board 602 by coupling components 628. The package-on-package structure 634 may include an IC package 626 and an IC package 632 coupled together by coupling components 630 such that the IC package 626 is disposed between the circuit board 602 and the IC package 632. The coupling components 628 and 630 may take the form of any of the embodiments of the coupling components 616 discussed above, and the IC packages 626 and 632 may take the form of any of the embodiments of the IC package 620 discussed above. The package-on-package structure 634 may be configured in accordance with any of the package-on-package structures known in the art.

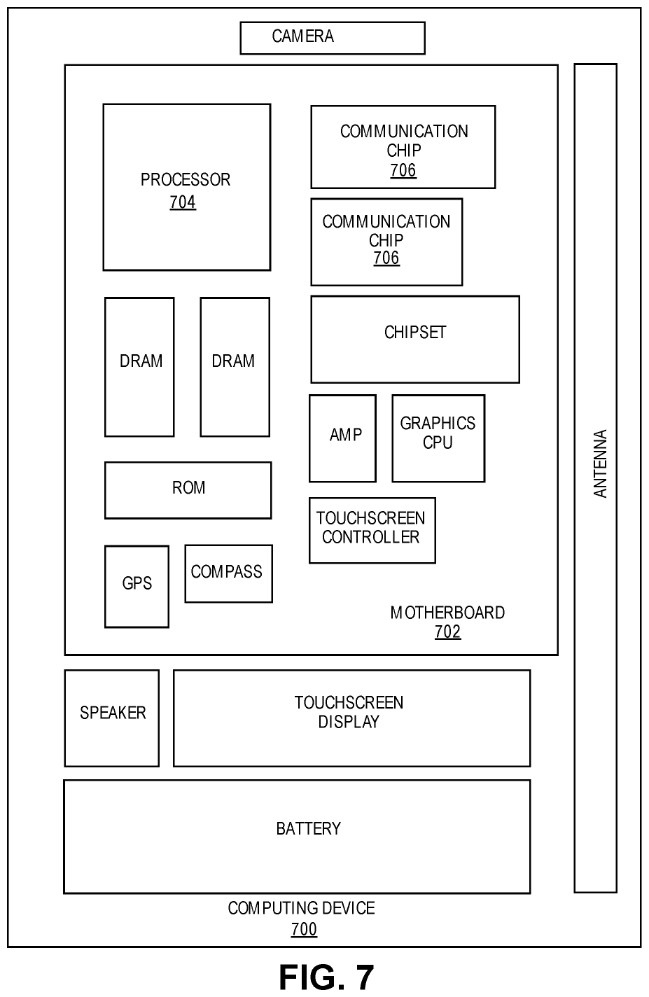

FIG. 7 illustrates a computing device 700 in accordance with one implementation of the disclosure. The computing device 700 houses a motherboard 702. The motherboard 702 may include a number of components, including but not limited to a processor 704 and at least one communication chip 706. The processor 704 is physically and electrically coupled to the motherboard 702. In some implementations the at least one communication chip 706 is also physically and electrically coupled to the motherboard 702. In further implementations, the communication chip 706 is part of the processor 704.

Depending on its applications, computing device 700 may include other components that may or may not be physically and electrically coupled to the motherboard 702. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit (IC) die packaged within the processor 704. In some implementations of the disclosure, the IC die of the processor includes one or more spin orbit torque devices with topological insulator and heavy metal insert, in accordance with implementations of embodiments of the disclosure. The term “processor” may refer to any device or portion of a device that processes electronic data from registers and/or memory to transform that electronic data into other electronic data that may be stored in registers and/or memory.

The communication chip 706 also includes an IC die packaged within the communication chip 706. In accordance with another implementation of embodiments of the disclosure, the IC die of the communication chip includes one or more spin orbit torque (SOT) devices with topological insulator (TI) and heavy metal insert, in accordance with implementations of embodiments of the disclosure.

In further implementations, another component housed within the computing device 700 may contain an IC die that includes one or more SOT devices with TI and heavy metal insert, in accordance with implementations of embodiments of the disclosure.

In various implementations, the computing device 700 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, the computing device 700 may be any other electronic device that processes data.

Thus, embodiments described herein include SOT devices with TI and heavy metal insert.

The above description of illustrated implementations of embodiments of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

The following examples pertain to further embodiments. The various features of the different embodiments may be variously combined with some features included and others excluded to suit a variety of different applications.

Example embodiment 1: An integrated circuit (IC) structure includes a spin orbit coupling (SOC) interconnect including a topological insulator (TI) material. A magnetic layer is above the SOC interconnect. An insert layer includes a heavy metal between and in contact with the TI material and the magnetic layer.

Example embodiment 2: The integrated circuit (IC) structure of example embodiment 1, wherein the magnetic layer is a free magnetic layer, and the IC structure further includes a tunneling barrier layer over the free magnetic layer and a fixed magnetic layer over the tunneling barrier layer.

Example embodiment 3: The integrated circuit (IC) structure of example embodiment 1 or 2, wherein the topological insulator (TI) material of the SOC interconnect includes a material selected from the group consisting of Bi₂Se₃, Bi₂Te₃, Sb₂Se₃, Sb₂Te₃ and BiₓSb₁₋ₓTe₃.

Example embodiment 4: The integrated circuit (IC) structure of example embodiment 1, 2 or 3, wherein the heavy metal of the insert layer includes tantalum, tungsten, iridium, platinum, or an alloy thereof.

Example embodiment 5: The integrated circuit (IC) structure of example embodiment 1, 2, 3 or 4, wherein the topological insulator (TI) material of the spin orbit coupling (SOC) interconnect has a thickness in the range of 5-15 nanometers, and the insert layer has a thickness in the range of 0.5-5 nanometers.

Example embodiment 6: An integrated circuit (IC) structure includes a spin orbit coupling (SOC) interconnect including a topological insulator (TI) material. An antiferromagnetic layer AFM is above the SOC interconnect. An insert layer includes a heavy metal between and in contact with the TI material and the antiferromagnetic layer AFM.

Example embodiment 7: The integrated circuit (IC) structure of example embodiment 6, wherein the magnetic layer is a free antiferromagnetic layer AFM, and the IC structure further includes a tunneling barrier layer over the free antiferromagnetic layer AFM and a fixed magnetic (FM) layer over the tunneling barrier layer.

Example embodiment 8: The integrated circuit (IC) structure of example embodiment 6 or 7, wherein the topological insulator (TI) material of the spin orbit coupling (SOC) interconnect includes a material selected from the group consisting of Bi₂Se₃, Bi₂Te₃, Sb₂Se₃, Sb₂Te₃ and BiₓSb₁₋ₓTe₃.

Example embodiment 9: The integrated circuit (IC) structure of example embodiment 6, 7 or 8, wherein the heavy metal of the insert layer includes tantalum, tungsten, iridium, platinum, or an alloy thereof.

Example embodiment 10: The integrated circuit (IC) structure of example embodiment 6, 7, 8 or 9, wherein the topological insulator (IC) material of the spin orbit coupling (SOC) interconnect has a thickness in the range of 5-15 nanometers, and the insert layer has a thickness in the range of 0.5-5 nanometers.

Example embodiment 11: An integrated circuit (IC) structure includes a spin orbit coupling (SOC) interconnect. A magnetic layer is above the SOC interconnect. An insert stack is between the SOC interconnect and the magnetic layer. The insert stack includes a plurality of alternating topological insulator (TI) material layers and heavy metal layers with one of the heavy metal layers in contact with the magnetic layer.

Example embodiment 12: The integrated circuit (IC) structure of example embodiment 11, wherein the magnetic layer is a free magnetic layer, and the IC structure further includes a barrier material over the free magnetic layer and a fixed magnetic layer over the barrier material.

Example embodiment 13: The integrated circuit (IC) structure of example embodiment 11 or 12, wherein the topological insulator (TI) material layers include a material selected from the group consisting of Bi₂Se₃, Bi₂Te₃, Sb₂Se₃, Sb₂Te₃ and BiₓSb₁₋ₓTe₃.

Example embodiment 14: The integrated circuit (IC) structure of example embodiment 11, 12 or 13, wherein the heavy metal layers include tantalum, tungsten, iridium, platinum, or an alloy thereof.

Example embodiment 15: The integrated circuit (IC) structure of example embodiment 11, 12, 13 or 14, wherein each of the topological insulator (TI) layers has a thickness in the range of 5-15 nanometers, and each of the heavy metal layers has a thickness in the range of 0.5-5 nanometers.

Example embodiment 16: An integrated circuit (IC) structure includes a spin orbit coupling (SOC) interconnect. An antiferromagnetic layer AFM is above the SOC interconnect. An insert stack is between the SOC interconnect and the antiferromagnetic layer AFM. The insert stack includes a plurality of alternating topological insulator (TI) material layers and heavy metal layers with one of the heavy metal layers in contact with the antiferromagnetic layer AFM.

Example embodiment 17: The integrated circuit (IC) structure of example embodiment 16, wherein the antiferromagnetic layer AFM is a free antiferromagnetic layer, and the IC structure further includes a barrier material over the free antiferromagnetic layer AFM and a fixed magnetic layer over the barrier material.

Example embodiment 18: The integrated circuit (IC) structure of example embodiment 16 or 17, wherein the topological insulator (TI) material layers include a material selected from the group consisting of Bi₂Se₃, Bi₂Te₃, Sb₂Se₃, Sb₂Te₃ and BiₓSb₁₋ₓTe₃.

Example embodiment 19: The integrated circuit (IC) structure of example embodiment 16, 17 or 18, wherein the heavy metal layers include tantalum, tungsten, iridium, platinum, or an alloy thereof.

Example embodiment 20: The integrated circuit (IC) structure of example embodiment 16, 17, 18 or 19, wherein each of the topological insulator (TI) layers has a thickness in the range of 5-15 nanometers, and each of the heavy metal layers has a thickness in the range of 0.5-5 nanometers.

What is claimed is:

1 An integrated circuit structure, comprising:
a spin orbit coupling (SOC) interconnect comprising a topological insulator (TI) material;
a magnetic layer above the SOC interconnect; and
an insert layer comprising a heavy metal between and in contact with the TI material and the magnetic layer.

2. The integrated circuit structure of claim 1, wherein the magnetic layer is a free magnetic layer, and the integrated circuit structure further comprises a barrier material over the free magnetic layer and a fixed magnetic layer over the barrier material.

3. The integrated circuit structure of claim 1, wherein the TI material of the SOC interconnect comprises a material selected from the group consisting of Bi₂Se₃, Bi₂Te₃, Sb₂Se₃, Sb₂Te₃ and BiₓSb₁₋ₓTe₃.

4. The integrated circuit structure of claim 1, wherein the heavy metal of the insert layer comprises tantalum, tungsten, iridium, platinum, or an alloy thereof.

5. The integrated circuit structure of claim 1, wherein the TI material of the SOC interconnect has a thickness in the range of 5-15 nanometers, and the insert layer has a thickness in the range of 0.5-5 nanometers.

6. An integrated circuit structure, comprising:
a spin orbit coupling (SOC) interconnect comprising a topological insulator (TI) material;
an antiferromagnetic layer (AFM) above the SOC interconnect; and
an insert layer comprising a heavy metal between and in contact with the TI material and the antiferromagnetic layer.

7. The integrated circuit structure of claim 6, wherein the antiferromagnetic layer AFM is a free antiferromagnetic layer AFM, and the integrated circuit structure further comprises a barrier material over the free antiferromagnetic layer AFM and a fixed magnetic layer over the barrier material.

8. The integrated circuit structure of claim 6, wherein the TI material of the SOC interconnect comprises a material selected from the group consisting of Bi₂Se₃, Bi₂Te₃, Sb₂Se₃, Sb₂Te₃ and BiₓSb₁₋ₓTe₃.

9. The integrated circuit structure of claim 6, wherein the heavy metal of the insert layer comprises tantalum, tungsten, iridium, platinum, or an alloy thereof.

10. The integrated circuit structure of claim 6, wherein the TI material of the SOC interconnect has a thickness in the range of 5-15 nanometers, and the insert layer has a thickness in the range of 0.5-5 nanometers.

11. An integrated circuit structure, comprising:
a spin orbit coupling (SOC) interconnect;
a magnetic layer above the SOC interconnect; and
an insert stack between the SOC interconnect and the magnetic layer, the insert stack comprising a plurality of alternating topological insulator (TI) material layers and heavy metal layers with one of the heavy metal layers in contact with the magnetic layer.

12. The integrated circuit structure of claim 11, wherein the magnetic layer is a free magnetic layer, and the integrated circuit structure further comprises a barrier material over the free magnetic layer and a fixed magnetic layer over the barrier material.

13. The integrated circuit structure of claim 11, wherein the TI material layers comprise a material selected from the group consisting of Bi₂Se₃, Bi₂Te₃, Sb₂Se₃, Sb₂Te₃ and BiₓSb₁₋ₓTe₃.

14. The integrated circuit structure of claim 11, wherein the heavy metal layers comprise tantalum, tungsten, iridium, platinum, or an alloy thereof.

15. The integrated circuit structure of claim 11, wherein each of the TI layers has a thickness in the range of 5-15 nanometers, and each of the heavy metal layers has a thickness in the range of 0.5-5 nanometers.

16. An integrated circuit structure, comprising:
a spin orbit coupling (SOC) interconnect;
an antiferromagnetic layer AFM above the SOC interconnect; and
an insert stack between the SOC interconnect and the antiferromagnetic layer AFM, the insert stack comprising a plurality of alternating TI material layers and heavy metal layers with one of the heavy metal layers in contact with the antiferromagnetic layer AFM.

17. The integrated circuit structure of claim 16, wherein the antiferromagnetic layer AFM is a free antiferromagnetic layer AFM, and the integrated circuit structure further comprises a barrier material over the free antiferromagnetic layer AFM and a fixed magnetic layer over the barrier material.

18. The integrated circuit structure of claim 16, wherein the TI material layers comprise a material selected from the group consisting of Bi₂Se₃, Bi₂Te₃, Sb₂Se₃, Sb₂Te₃ and BiₓSb₁₋ₓTe₃.

19. The integrated circuit structure of claim 16, wherein the heavy metal layers comprise tantalum, tungsten, iridium, platinum, or an alloy thereof.

20. The integrated circuit structure of claim 16, wherein each of the TI layers has a thickness in the range of 5-15 nanometers, and each of the heavy metal layers has a thickness in the range of 0.5-5 nanometers.
